(19) United States
(12) Patent Application Publication
(10) Pub. No.: US 2007/0262350 A1
(43) Pub. Date: Nov. 15, 2007

(54) Semiconductor integrated circuit device

(75) Inventor: Shuichi Nagase, Tokyo (JP)

Correspondence Address: Paul J. Esatto, Jr.;Scully, Scott, Murphy & Presser, P.C., Suite 300, 400 Garden City Plaza, Garden City, NY, 11530, US

(73) Assignee: Elpida Memory, Inc., Tokyo (JP)

(21) Appl. No.: 11/800,579

(22) Filed: May 7, 2007

(30) Foreign Application Priority Data
May 12, 2006 (JP) 2006-133878

(51) Int. Cl. H01L 27/10

(52) U.S. Cl. 257/206

(57) ABSTRACT

Semiconductor integrated circuit device wherein action for averting antenna effect has been taken, and method for producing a semiconductor integrated circuit device in which action for averting the antenna effect can be taken with ease. The method for producing a semiconductor integrated circuit device includes forming step of forming a semiconductor region of first conductivity type, a first diffusion region of the first conductivity type, formed in the semiconductor region of the first conductivity type, a gate insulating film formed in the semiconductor region of the first conductivity type, gate electrode on the gate insulating film and a wiring layer electrically connected to the gate electrode. The method also includes an investigating step of investigating, following the forming step, into whether or not it is necessary to take an action for averting an antenna effect in the wiring layer. The method also includes an action-taking step of replacing the first diffusion region of the first conductivity type by a second diffusion region of a second conductivity type, in case it is verified in the investigating step that it is necessary to take an action against the antenna effect. The second diffusion region of the second conductivity type forms a pn junction with the semiconductor region of the first conductivity type. The action-taking step also electrically connects the second region of the second conductivity type to the wiring layer.

### FIELD OF THE INVENTION

This invention relates to a semiconductor integrated circuit device for preventing destruction of a gate insulating film under an antenna effect, and to a method for fabrication of the semiconductor integrated circuit device.

### BACKGROUND OF THE INVENTION

Recently, as a semiconductor device is miniaturized in size, the gate insulating film is also becoming thinner in thickness. As a result, problems are raised in connection with destruction of the gate insulating film by the antenna effect. The “antenna effect” means charge accumulation in a wiring layer, electrically connected to a gate electrode, during the process of generating the wiring layer, especially during a plasma etching process, because of lack of a discharge path from the wiring layer. If, under the antenna effect, the quantity of electrical charges, accumulated in the wiring layer, exceeds a predetermined value, a gate insulating film, connected to the wiring layer, is stressed with a high electrical field, and hence is possibly destroyed.

FIG. 13 depicts a schematic plan view for illustrating the destruction of the gate insulating film by the antenna effect, and FIG. 14 depicts a schematic cross-sectional view thereof. In more detail, FIG. 13 depicts a schematic plan view showing a gate electrode and -wiring layers electrically connected to the gate electrode, and FIG. 14 depicts a side view of the components shown in FIG. 13. In FIGS. 13 and 14, a first wiring layer 34 is connected to a gate electrode 31 of a transistor via a contact 38. The first wiring layer 34 is connected via a via 39 to an upper-level second wiring layer 35. This second wiring layer 35 is a wiring (interconnect) layer of a wider area extending transversely in FIG. 13. Electrical charges are accumulated on this second wiring layer 35 of the broader area during e.g., a plasma etching process. During the plasma etching process, the second wiring layer 35 is not electrically connected to e.g., a semiconductor substrate 41, so that there lacks a discharge path of the accumulated electrical charges. As a result, a gate insulating film 37 is stressed with a high electrical field from the second wiring layer 35 and hence may possibly be destroyed. The larger the area of the wiring layer or layers, as in the case of the second wiring layer 35, shown in FIG. 13, the higher becomes the risk of destruction of the gate insulating film 37.

To prevent destruction of the gate insulating film under the antenna effect, an attempt has been taken to set the antenna ratio to not higher than a preset value to decrease the quantity of electrical charges accumulated in the wiring layer (or layers) as well as to relieve the stress applied per unit area of the gate insulating film. The antenna ratio is the ratio of the surface area of the wiring layer (or layers) to the gate channel area. For example, Patent Document 1 describes a layout method for a semiconductor integrated circuit device in which a wiring barrier region, surrounding circuit blocks in the form of a ring, is provided as an uppermost layer. The circuit blocks are interconnected via this wiring barrier region to diminish the antenna ratio within the circuit blocks. Patent Document 2 describes a method for fabrication of a semiconductor integrated circuit device, in which a standard cell, having a wiring extending the uppermost wiring layer, is inserted into a layout which is likely to be plagued with the antenna effect, to prevent destruction of the gate insulating film.

As another attempt for preventing destruction of the gate insulating film by the antenna effect, there is a method of connecting a protective device to a wiring layer connected to a gate electrode to secure a discharge path for electrical charges accumulated in the wiring layer. For example, in a layout method for a semiconductor integrated circuit device, disclosed in Patent Document 3, a diode is connected as a protective device to a wiring which is in need of a preventive action against the antenna effect.

[Patent Document 1] JP Patent Kokai Publication No. JP-P2002-289695A

[Patent Document 2] JP-Patent Kokai Publication No. JP-A-11-186394

[Patent Document 3] JP-Patent Kokai Publication No. JP-P2001-237322A

### SUMMARY OF THE DISCLOSURE

According to the present invention, the following analyses are given on the related art. The aforementioned documents are herein incorporated by reference thereto.

In the method for averting the antenna effect by taking advantage of a wiring of the uppermost layer, a wiring or interconnect in need of prevention against the antenna effect cannot be connected via a desired route to the wiring of the uppermost layer in case the vicinity of the uppermost layer wiring is over-crowded. Hence, to connect the wiring in need of the prevention to the uppermost layer wiring, the wiring in need of the preventive action and the via need to be formed as a pre-existing device or devices is by-passed. In this case, it is highly probable that capacitance of the by-passing wiring is generated to affect circuit characteristics. Moreover, in case connection has to be made through the uppermost wiring layer, there are placed limitations on the degree of freedom in the layout construction.

With the method of inserting a cell or a protective device, as in Patent Document 2 or 3, there may be cases where the cell or the protective device or devices cannot be inserted due to shortage of the layout area because a site where a cell or a protective device or devices is to be located may be found only after the wiring or after the designing for wiring is finished. Moreover, to provide a discharge path from the wiring layer in need of the preventive action against the antenna effect to the semiconductor substrate, it becomes necessary to secure a region for discharge in the substrate beforehand at layout. However, since the site where it is necessary to take an action for averting the antenna effect may be known only after completing the wiring or subsequent to layout designing, it is difficult to determine the region for discharge. If the wiring to the discharge region has to be formed by a by-pass route, circuit characteristics may be affected in the same way as described above.

Accordingly, it is an object of the present invention to provide a semiconductor integrated circuit device on which measures for averting the antenna effect have been taken, and a method for fabricating a semiconductor integrated circuit device for which measures for averting the antenna effect may be taken with ease.

In a first aspect, the present invention provides a semiconductor integrated circuit device comprising: a semiconductor region of a first conductivity type; a gate electrode and a gate insulating film, formed in the semiconductor region of the first conductivity type; at least one wiring layer electrically connected to the gate electrode, and a first diffusion region formed in the semiconductor region of the first conductivity type. The first diffusion region is formed by electrically isolating part of a body contact or a well contact from the body contact or the well contact, respectively. The first diffusion region forms a pn junction with a region surrounding the first diffusion region. The first diffusion region is electrically connected to the at least one wiring layer to act as a discharge path for electrical charges accumulated in the at least one wiring layer.

In a preferred form in the first aspect, the first diffusion region is of a second conductivity type and forms a pn junction with the semiconductor region of the first conductivity type. It is preferred that the first conductivity type is a p type and the second conductivity type is an n type.

In a further preferred form in the first aspect, the semiconductor integrated circuit device further includes a second diffusion region of a second conductivity type. The first diffusion region is of the first conductivity type and surrounded by the second diffusion region of the second conductivity type to form a pn junction with the second diffusion region of the second conductivity type. In a further preferred form, the first conductivity type is the n type and the second conductivity type is the p type.

In a preferred form in the first aspect, the first diffusion region is formed on a rim part of a cell.

In a preferred form of the first aspect, the semiconductor integrated circuit device includes a complementary metal oxide semiconductor (CMOS) provided with the semiconductor region of the first conductivity type and a semiconductor region of a second conductivity type. The first diffusion region is arranged between the semiconductor region of the second conductivity type and the body contact or the well contact.

In a second aspect, the present invention provides a method for producing a semiconductor integrated circuit device wherein, in averting the antenna effect in a wiring layer connected to a gate electrode, part of a region of the body contact or well contact is electrically isolated from the body contact or well contact and used as a discharge path for electrical charges accumulated in the wiring layer.

In a preferred form of the second aspect, a pn junction is formed by the part of the region of the body contact or well contact and a region surrounding the part of the region.

In a third aspect, the present invention provides a method for producing a semiconductor integrated circuit device including a forming step, an investigating step and an action-taking step. The forming step forms a semiconductor region of a first conductivity type, a first diffusion region of a first conductivity type, formed in the semiconductor region of the first conductivity type, a gate insulating film formed in the semiconductor region of the first conductivity type, a gate electrode on the gate insulating film and a wiring layer electrically connected to the gate electrode. The investigating step investigates, following the forming step, into whether or not it is necessary to take an action for averting an antenna effect in the wiring layer. The action-taking step replaces the first diffusion region of the first conductivity type by a second diffusion region of a second conductivity type, in case it is verified in the investigating step that it is necessary to take an action against the antenna effect. The second diffusion region of the second conductivity type forms a pn junction with the semiconductor region of the first conductivity type. The action-taking step also electrically connects the second region of the second conductivity type to the wiring layer.

In a preferred form in the third aspect, the first diffusion region of the first conductivity type is formed in the forming step as a body contact or as a well contact. In the action-taking step, a part of a region of the body contact or the well contact is electrically isolated from the body contact or the well contact. The part of the region is replaced by the second diffusion region of the second conductivity type.

In a fourth aspect, the present invention provides a method for producing a semiconductor integrated circuit device including a forming step, an investigating step and an action-taking step. The forming step forms a semiconductor region of a first conductivity type, a first diffusion region of the first conductivity type, formed in the semiconductor region of the first conductivity type, a gate insulating film formed in the semiconductor region of the first conductivity type, a gate electrode on the gate insulating film and a wiring layer electrically connected to the gate electrode. The investigating step investigates, following the forming step, into whether or not it is necessary to take an action for averting an antenna effect in the wiring layer. The action-taking step replaces the semiconductor region of the first conductivity type, surrounding the first diffusion region of the first conductivity type, by a second diffusion region of a second conductivity type, in case it is verified in the investigating step that it is necessary to take an action against the antenna effect. The first diffusion region of the first conductivity type forms a pn junction with the second semiconductor region of the second conductivity type. The action-taking step also electrically connects the first diffusion region of the first conductivity type to the wiring layer.

In a preferred form of the fourth aspect, the first diffusion region of the first conductivity type is formed in the forming step as a body contact or as a well contact. In the action-taking step, a part of a region of the body contact or the well contact is electrically isolated from the body contact or the well contact. The semiconductor region of the first conductivity type surrounding the part of the region is replaced by the second diffusion region of the second conductivity type.

In a preferred form of the third and fourth aspects, a third diffusion region of the first conductivity type is further formed in the semiconductor region of the first conductivity type. The third diffusion region of the first conductivity type is arranged in isolation from the first diffusion region of the first conductivity type and electrically connected to the first diffusion region of the first conductivity type. In the action-taking step, the first diffusion region of the first conductivity type and the third diffusion region of the first conductivity type are electrically isolated from each other. In a further preferred form, the first diffusion region of the first conductivity type and the third diffusion region of the first conductivity type are formed in the forming step as a body contact or as a well contact. In the action-taking step, the first diffusion region of the first conductivity type is formed as a discharge path and the third diffusion region of the first conductivity type is formed as a body contact or as a well contact.

The meritorious effects of the present invention are summarized as follows.

According to the present invention, discharge paths from the wiring layer which is in need of the antenna effect preventive action may be secured without the need of a larger space and without the necessity of significant corrections or alterations in layout. Especially, in case an action against the antenna effect is necessary, part of the region of a body contact or a well contact may be used as a discharge path. Consequently, the discharge path can be generated extremely readily. Moreover, since it is unnecessary to provide a wiring for by-passing the pre-existing device, or a wiring of only a shorter length suffices, there is only little possibility of affecting circuit characteristics.

### BRIEF DESCRIPTION OF THE DRAWINGS

FIG. 1 is a schematic plan view showing the layout of a semiconductor integrated circuit device of the present invention.

FIG. 2 is a schematic cross-sectional view taken along line A-A of FIG. 1.

FIG. 3 is a schematic plan view of a semiconductor integrated circuit device according to a first example of the present invention.

FIG. 4 is a schematic cross-sectional view taken along line B-B of FIG. 3.

FIG. 5 is a schematic plan view of a semiconductor integrated circuit device according to a second example of the present invention.

FIG. 6 is a schematic cross-sectional view taken along line C-C of FIG. 5.

FIG. 7 is a schematic cross-sectional view taken along line D-D of FIG. 5.

FIG. 8 is a schematic plan view of a semiconductor integrated circuit device according to a third example of the present invention.

FIG. 9 is a schematic cross-sectional view taken along line E-E of FIG. 5.

FIG. 10 is a schematic cross-sectional view taken along line F-F of FIG. 5.

FIG. 11 is a schematic plan view of a semiconductor integrated circuit device according to a fourth example of the present invention.

FIG. 12 is a schematic plan view of a semiconductor integrated circuit device according to a fifth example of the present invention.

FIG. 13 is a schematic plan view for explaining the destruction of a gate insulating film by the antenna effect.

FIG. 14 is a side view showing components shown in FIG. 13.

### PREFERRED MODES OF THE DISCLOSURE

A semiconductor integrated circuit device and a method for producing the device, according to the present invention, will now be described with reference to a case of a complementary metal oxide semiconductor (CMOS) including a p type semiconductor substrate and an n-well generated in the substrate.

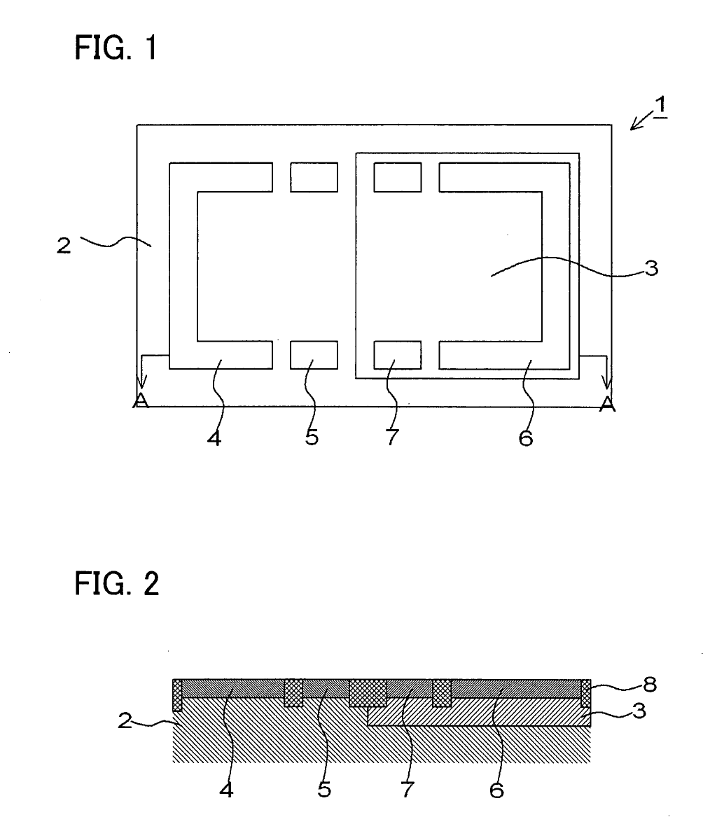

Referring first to FIGS. 1 and 2, an example of layout of a semiconductor integrated circuit device according to the present invention is now described. FIG. 1 depicts a schematic plan view showing a layout in a semiconductor integrated circuit device 1, and FIG. 2 depicts a schematic cross-sectional view along line A-A of FIG. 1. Meanwhile, in the plan view of the present invention, a silicon oxide film is omitted from the drawing for clarifying the area of e.g., a diffusion region. The semiconductor integrated circuit device 1 includes a p type semiconductor substrate 2, as a semiconductor region, and an n-well 3, as a semiconductor region formed in the p type semiconductor substrate 2. In the p type semiconductor substrate 2 and in the n-well 3, there are formed a body contact or substrate contact 4 and a well contact 6, as diffusion regions, respectively. These contacts 4, 6 are generally U-shaped and are formed extending along the rim of a basic circuit cell, not shown in detail. In the configuration shown in FIG. 1, there are formed diffusion regions 5 between the body contact 4 and the n-well 3, so that the diffusion regions 5 are isolated, that is, made independent from, the body contact 4 from the outset. There are also formed diffusion regions 7 between the well contact 6 and the p type semiconductor substrate 2, so that the diffusion regions 7 are isolated, that is, made independent from, the well contact 6 from the outset. According to the present invention, the diffusion regions 5 and 7 are used as a body contact or as a well contact, respectively, in case the antenna effect averting action is not needed. The diffusion regions 5 and 7 are used as a discharge path in case the antenna effect averting action is needed. Preferred examples of the present invention are now described in detail.

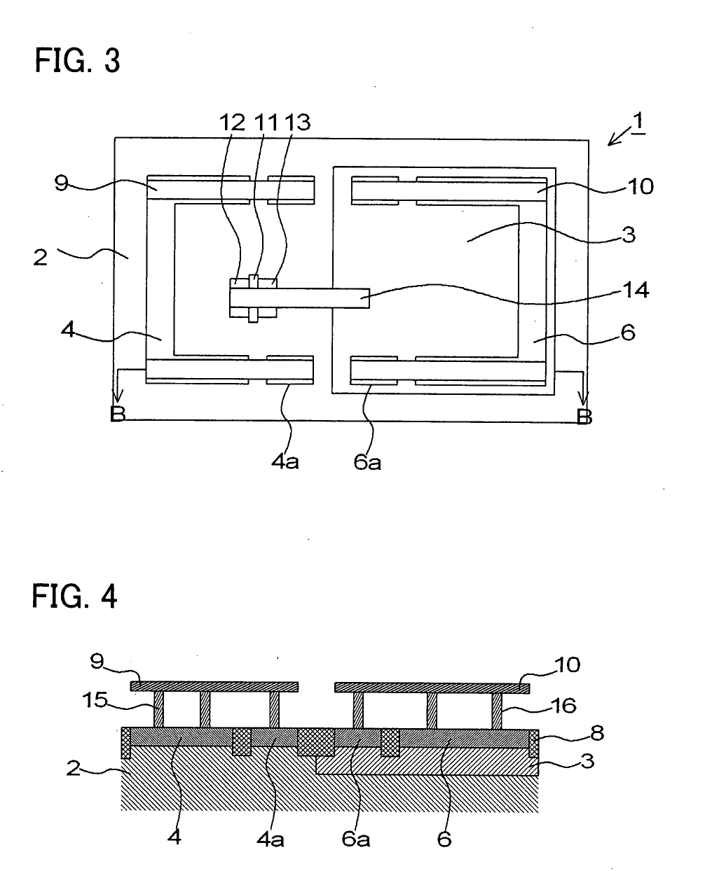

The semiconductor integrated circuit device according to a first example of the present invention is now described. In a layout of the semiconductor integrated circuit device 1 of the first example, shown in FIGS. 1 and 2, no antenna effect averting action is taken, that is, the diffusion regions 5 and 7 are used as a body contact and as a well contact, respectively. FIG. 3 depicts a schematic plan view of a semiconductor integrated circuit device of the first example, and FIG. 4 depicts a schematic cross-sectional view taken along line B-B of FIG. 3.

In the semiconductor integrated circuit device 1, a MOS field effect transistor (FET) is formed in the p type semiconductor substrate 2. The MOSFET includes a gate electrode 11, a source 12, a drain 13 and a gate insulating film, not shown in FIG. 3. To the gate electrode 11, there is connected a third wiring layer 14 via a contact, not shown. The diffusion regions 5 are diffusion regions of the p type which is the same conductivity type as that of the body contact 4, and are labeled 4a. The body contact 4 and each first conductivity type diffusion region 4a are electrically connected to each other via a first contact 15 and a first wiring (interconnect) layer 9, and hence the first conductivity type diffusion region 4a may operate as a body contact. Similarly, the second conductivity type diffusion regions 7 are diffusion regions of an n type, which is the same conductivity type as that of the well contact 6, and are labeled 6a. The well contact 6 and each second conductivity type diffusion region 6a are electrically connected to each other via a second contact 16 and a second wiring layer 10, and hence the second conductivity type diffusion region 6a may operate as a well contact.

In the first example, the case in which the MOSFET is in a p type semiconductor substrate 2 has been described. However, the above applies for a case in which the MOSFET is in an n type semiconductor substrate 3.

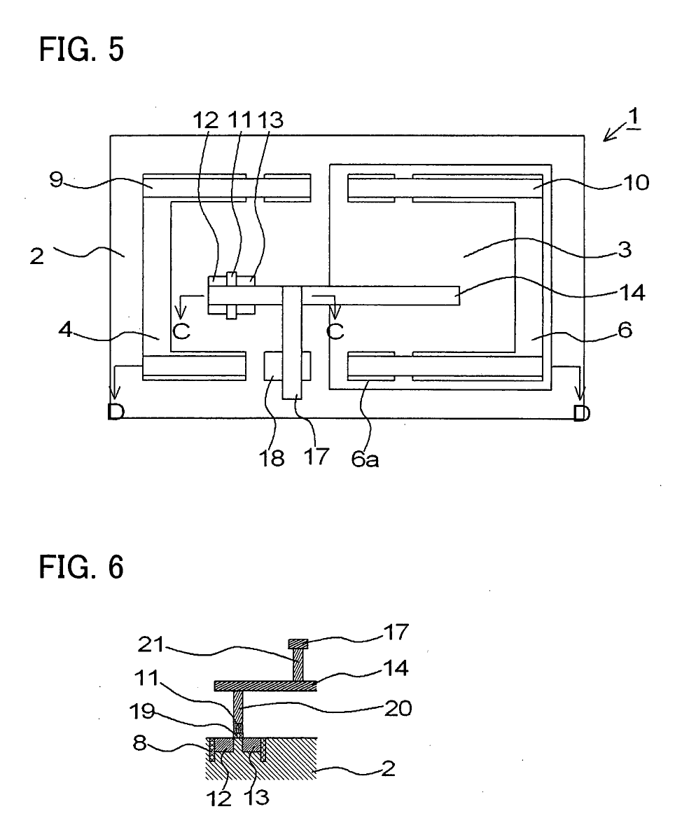

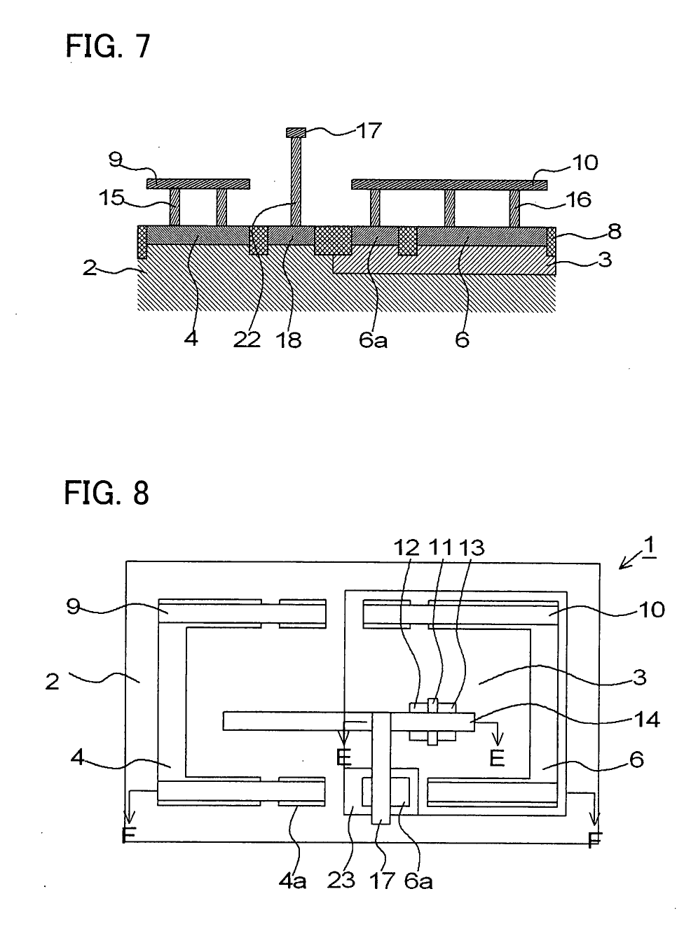

A semiconductor integrated circuit device according to a second example of the present invention and the method for fabrication of the same will now be described. In the first example, the semiconductor integrated circuit device is of the form in which an antenna effect averting action is not required. Stated differently, the semiconductor integrated circuit device is shown in a form prior to applying the antenna effect averting action. In the second example, the semiconductor integrated circuit device is of the form in which the antenna effect averting action has been taken, that is, the device is shown in the form in which the diffusion regions 5 are used as a discharge path. FIG. 5 depicts a schematic plan view showing a semiconductor integrated circuit device according to the second example of the present invention. FIGS. 6 and 7 depict schematic cross-sectional views taken along lines C-C and D-D of FIG. 5, respectively.

The semiconductor integrated circuit device, shown in FIGS. 3 and 4, is already fabricated, that is, respective components of the device are formed and the wiring (or interconnection) of respective wiring layers is finished. It is then checked whether or not there is possibility of the antenna effect taking place in connection with e.g., the third wiring layer 14. If it is recognized to be necessary to take an antenna effect preventive action, such action is taken for e.g., the third wiring layer 14. A decision as to whether or not it is necessary to take the antenna effect preventive action may be given based on a desired standard or reference.

It is assumed that it has become necessary to take the antenna effect preventive action for a wiring layer connected to the gate electrode 11, for example, the third wiring layer 14 or the fourth wiring layer 17. In this case, the first wiring layer 9 and the first contact 15, connected to the first conductivity type diffusion region 4a (the region corresponding to the diffusion region 5 shown in FIGS. 1 and 2) are removed. The region corresponding to the diffusion region 5 is now changed from the p type diffusion region 4a to an n type diffusion region 18, such as an ion injection layer. This generates a pn junction provided by the n type diffusion region 18 and the p type semiconductor region 2. The fourth wiring layer 17, formed on top of the third wiring layer 14, and the n type diffusion region 18, are interconnect by a contact 22. The fourth wiring layer 17 and the third wiring layer 14 are interconnected via a via 21. This electrically connects the n type diffusion region 18 to the third wiring layer 14 which is in need of the antenna effect preventive action.

If, in this configuration, the electrical charges stored in the wiring (interconnect) layers connected to the gate electrode 11, for example, the third wiring layer 14 and the fourth wiring layer 17, exceed the reverse voltage provided by the pn junction of the n type diffusion region 18 and the p type semiconductor region 2, the charges are discharged to the semiconductor region of the first conductivity type 2. The reverse voltage is the forward bias of the pn junction and hence is sufficiently smaller than the voltage which might destruct a gate insulating film 19. Hence, the region corresponding to the diffusion region 5 may be in operation as a discharge path.

Thus, in the semiconductor integrated circuit device and the method for fabrication thereof, according to the second example, part of the body contact may be used as a discharge path, whereby the antenna effect may be prevented from being generated without the necessity of newly securing a region for a discharge path without forming a by-pass wiring.

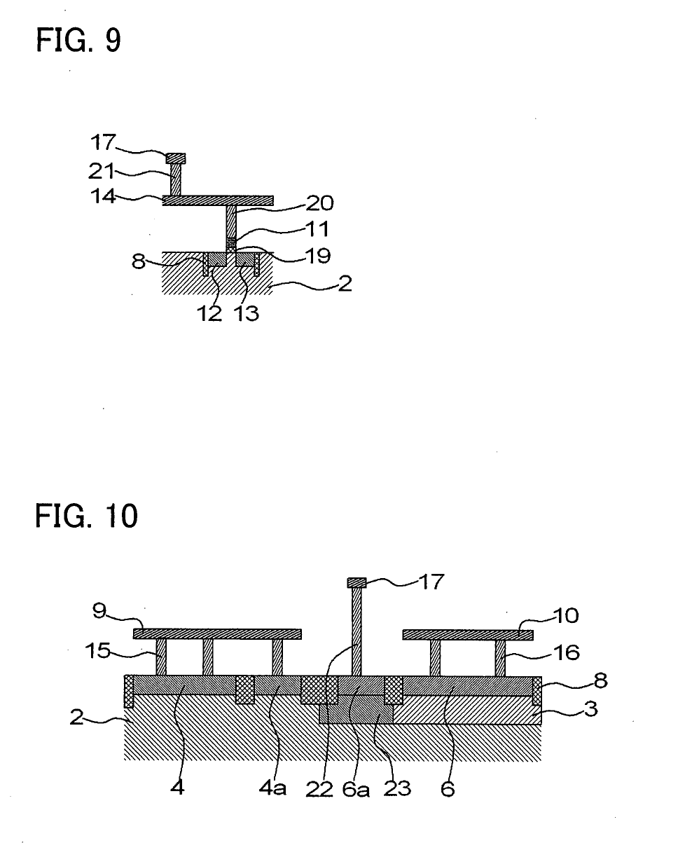

A semiconductor integrated circuit device and a method for fabrication thereof, according to a third example of the present invention, will now be described. In the second example, the antenna effect preventive action needs to be taken for the wiring layer connected to the MOSFET formed in the p type semiconductor substrate 2. In the present third example, the antenna effect preventive action needs to be taken for the wiring layer connected to the MOSFET formed in the n-well 3. FIG. 8 depicts a schematic plan view of a semiconductor integrated circuit device according to the third example. FIGS. 9 and 10 depict cross-sectional views taken along lines E-E and F-F in FIG. 8, respectively.

Initially, such a semiconductor integrated circuit device is fabricated, in which a MOSFET is formed in the n-well 3, and in which the diffusion region 7 is used as part of the well contact (n type diffusion layer 6a), as shown in FIGS. 3 and 4. If it is verified that an action needs to be taken for averting the antenna effect, the second wiring layer 10 and the second contact 16, so far connected to the n type diffusion region 6a, are removed. The portion of the n-well 3, overlying or surrounding the n type diffusion region 6a, is then scraped off and replaced by a p type diffusion region 23 (e.g., an ion injection layer). The n type diffusion layer 6a and the fourth wiring layer 17 are then interconnected by a contact 22, as in the second example. The third wiring layer 14 and the fourth wiring layer 17 are interconnected by a via 21. By so doing, a pn junction is generated by the n type diffusion region 6a and the p type diffusion region 23 so that the n type diffusion region 6a may be used as a discharge path for electrical charges stored in the wiring layer.

Thus, with the second and third examples, part of the body contact or the well-contact may be used as a discharge path for averting the antenna effect, no matter whether the wiring in need of the antenna effect preventive action is in a p type semiconductor region or in an n type semiconductor region.

In the second and third examples, a semiconductor integrated circuit device is used in which the diffusion layers 5 and 7 are isolated from the outset from the body contact 4 and from the well-contact 6, respectively, as shown in FIG. 1. It is however possible to form the diffusion regions 18, 23, operating as discharge paths, from a unitary or non-interrupted structure made up of diffusion regions 5, 7, the body contact 4 and the well-contact 6.

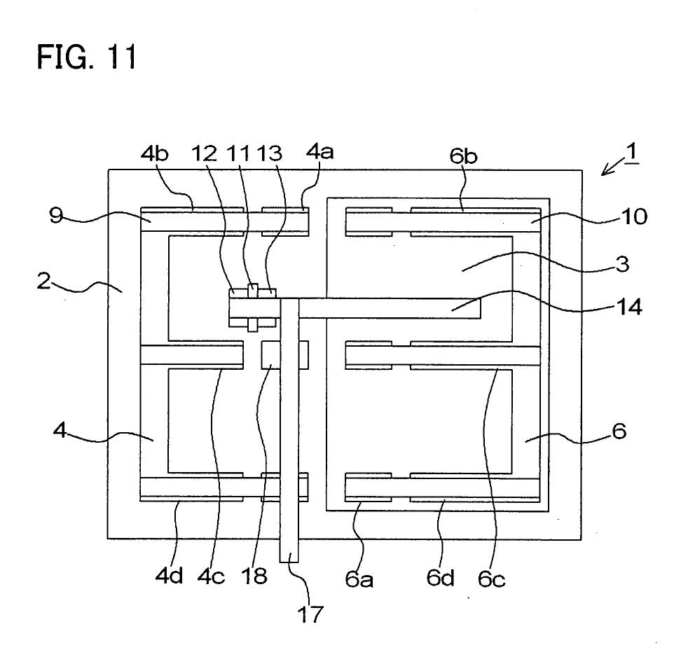

A semiconductor integrated circuit device and a method for fabrication thereof, according to a fourth example of the present invention, will now be described. It is noted that the basic structure of the second and third examples is a unitary basic circuit cell, while that of the fourth example is a parallel array of a plural number of basic circuit cells. FIG. 11 depicts a schematic plan view of a semiconductor integrated circuit device according to the fourth example of the present invention.

A semiconductor integrated circuit device shown in FIG. 11 is composed of two basic circuit cells of the same profile arrayed vertically in the drawing. On the rim of each basic circuit cell, there are formed a body contact 4 and a well contact 6 in a lattice configuration. A body contact 4c and a well contact 6c, provided at a mid portion between the two basic circuit cells, are shared by the two basic circuit cells. As in the first to third examples, a diffusion region, formed in isolation from the body contact 4, is formed between the body contact 4 and the n-well 3, while another diffusion region, formed in isolation from the well contact 6, is formed between the well contact 6 and a p type semiconductor substrate 2. As in the second example, a MOSFET is formed on the p type semiconductor substrate 2, while a third wiring layer 14 and so forth are connected to a gate electrode 11. In case the wiring layer connected to the gate electrode 11 is in need of an action against the antenna effect, an isolated diffusion region, neighboring to the body contact 4c, is replaced by an n type diffusion layer 18, as in the second example. A fourth wiring layer 17 and the n type diffusion region 18 are electrically connected to each other. This allows electrical charges stored in the wiring layers 14, 17 to be discharged via n type diffusion layer 18. In the configuration shown in FIG. 11, the diffusion regions 4a, separated from the body contacts 4b, 4d, are electrically connected to the first wiring layer 9 to act a part of the body contact 4.

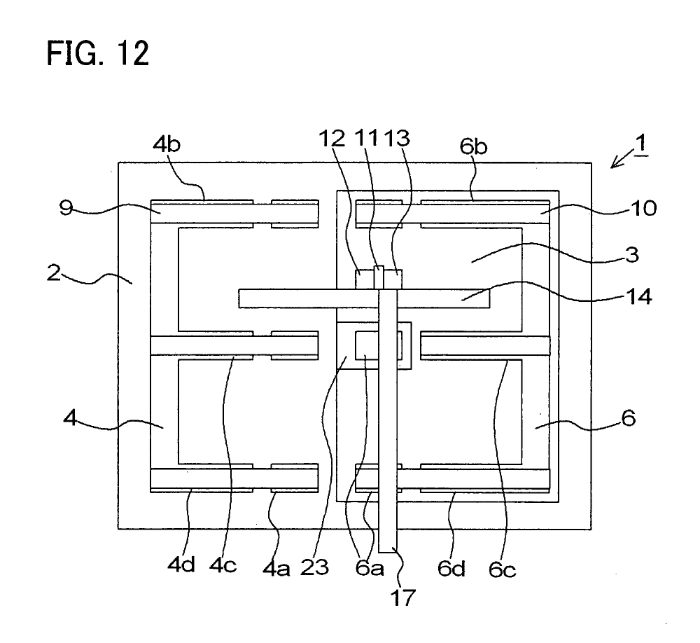

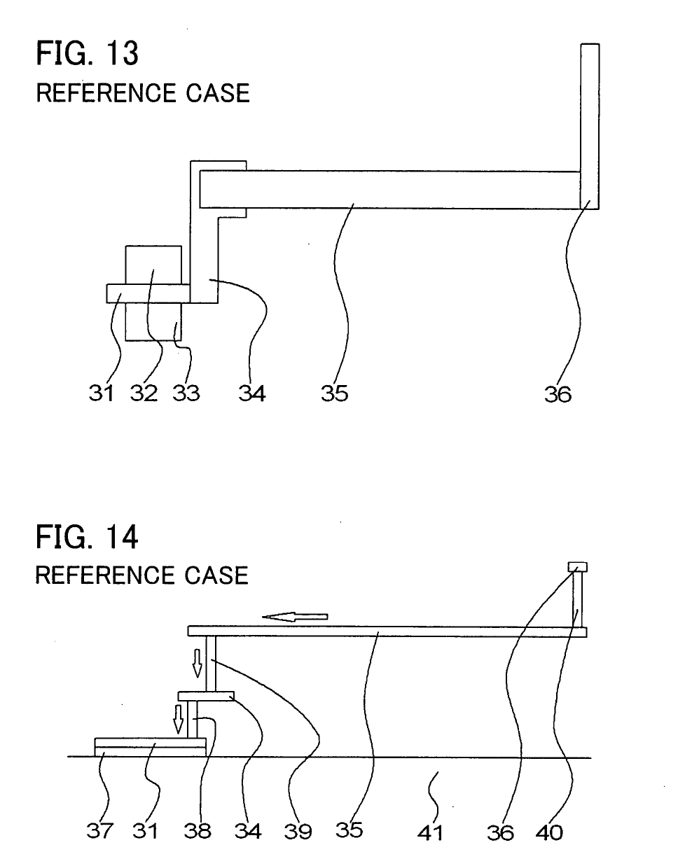

A semiconductor integrated circuit device, and a method for fabrication thereof, according to a fifth example of the present invention, will now be described. In the fourth example, the wiring layer connected to the MOSFET formed in the p type semiconductor substrate 2 is in need of an action against the antenna effect. In the present fifth example, the wiring layer connected to the MOSFET formed in the n-well 3 is in need of an action against the antenna effect. FIG. 12 depicts a schematic plan view of the semiconductor integrated circuit device according to the fifth example.

The semiconductor integrated circuit device, shown in FIG. 12, has the configuration similar to that of the device of the fourth example shown in FIG. 11. However, a MOSFET is formed in an n-well 3. In case an action against the antenna effect is needed, the portion of the n-well 3 surrounding the diffusion region 6a, neighboring to the well contact 6c, is replaced by a p type diffusion region 23, which p type diffusion region 23 is then electrically connected to a fourth wiring layer 17. This allows electrical charges, stored in the wiring layers 14, 17, to be discharged via diffusion region 6a and p type diffusion region 23. Meanwhile, the isolated diffusion regions 6a, neighboring to the well contacts 6b, 6d, are electrically connected to second wiring layers 10 to operate as part of the well contact 6.

With the fourth and fifth examples, part of the region of the body contact or well contact, shared by plural basic circuit cells, may be utilized as a discharge path for averting the antenna effect.

The above-described examples of the semiconductor integrated circuit device are merely illustrative of the present invention. It is to be appreciated that those skilled in the art can change or modify the examples without departing from the scope and spirit of the invention.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor integrated circuit device comprising:
a semiconductor region of a first conductivity type;
a gate electrode and a gate insulating film, formed in said semiconductor region of the first conductivity type;
at least one wiring layer electrically connected to said gate electrode; and
a first diffusion region formed in said semiconductor region of the first conductivity type; wherein
said first diffusion region is formed by electrically isolating part of a body contact or a well contact from said body contact or said well contact, respectively; said first diffusion region forming a pn junction with a region surrounding said first diffusion region; and
said first diffusion region is electrically connected to said at least one wiring layer to act as a discharge path for electrical charges accumulated in said at least one wiring layer.

2. The semiconductor integrated circuit device according to claim 1 wherein said first diffusion region is of a second conductivity type and forms a pn junction with said semiconductor region of the first conductivity type.

3. The semiconductor integrated circuit device according to claim 2 wherein said first conductivity type is a p type and said second conductivity type is an n type.

4. The semiconductor integrated circuit device according to claim 1 further comprising:
a second diffusion region of a second conductivity type;
said first diffusion region being of the first conductivity type and surrounded by said second diffusion region of the second conductivity type to form a pn junction with said second diffusion region of the second conductivity type.

5. The semiconductor integrated circuit device according to claim 4 wherein said first conductivity type is an n type and said second conductivity type is a p type.

6. The semiconductor integrated circuit device according to claim 1 wherein said first diffusion region is formed on a rim part of a cell.

7. The semiconductor integrated circuit device according to claim 1 comprising:
a complementary metal oxide semiconductor CMOS provided with said semiconductor region of said first conductivity type and a semiconductor region of a second conductivity type; wherein
said first diffusion region is arranged between said semiconductor region of the second conductivity type and said body contact or said well contact.

8. A method for producing a semiconductor integrated circuit device comprising:
providing a gate electrode and an wiring layer connected to the gate electrode, both disposed on a substrate;
electrically isolating part of a region of a body contact or well contact from said body contact or well contact to form a discharge path for electrical charges accumulated in said wiring layer, thereby averting the antenna effect.

9. The method for producing a semiconductor integrated circuit device according to claim 8 wherein a pn junction is formed by said part of the region and a region surrounding said part of the region.

10. A method for producing a semiconductor integrated circuit device comprising:
a forming step including: forming a semiconductor region of a first conductivity type, a first diffusion region of the first conductivity type, formed in said semiconductor region of the first conductivity type, a gate insulating film formed in said semiconductor region of the first conductivity type, a gate electrode on said gate insulating film and a wiring layer electrically connected to said gate electrode;
investigating, following said forming step, into whether or not it is necessary to take an action for averting an antenna effect in said wiring layer; and
an action-taking step of replacing said first diffusion region of said first conductivity type by a second diffusion region of a second conductivity type, in case it is verified in said investigating step that it is necessary to take an action against the antenna effect;
said second diffusion region of the second conductivity type forming a pn junction with said semiconductor region of the first conductivity type;
said action-taking step also electrically connecting said second region of the second conductivity type to said wiring layer.

11. The method for producing a semiconductor integrated circuit device according to claim 10 wherein,
in said forming step, said first diffusion region of the first conductivity type is formed as a body contact or as a well contact;
in said action-taking step, a part of a region of said body contact or said well contact is electrically isolated from said body contact or said well contact; and wherein
said part of the region is replaced by said second diffusion region of the second conductivity type.

12. A method for producing a semiconductor integrated circuit device comprising:
a forming step including: forming a semiconductor region of a first conductivity type, a first diffusion region of the first conductivity type, formed in said semiconductor region of the first conductivity type, a gate insulating film formed in said semiconductor region of the first conductivity type, a gate electrode on said gate insulating film and a wiring layer electrically connected to said gate electrode;
investigating, following said forming step, into whether or not it is necessary to take an action for averting an antenna effect in said wiring layer; and
an action-taking step of replacing said semiconductor region of said first conductivity type, surrounding said first diffusion region of said first conductivity type, by a second diffusion region of a second conductivity type, in case it is verified in said investigating step that it is necessary to take an action against the antenna effect;
said first diffusion region of the first conductivity type forming a pn junction with said second semiconductor region of the second conductivity type;
said action-taking step also electrically connecting said first diffusion region of the first conductivity type to said wiring layer.

13. The method for producing a semiconductor integrated circuit device according to claim 12 wherein,
in said forming step, said first diffusion region of the first conductivity type is formed as a body contact or as a well contact;
in said action-taking step, a part of a region of said body contact or said well contact is electrically isolated from said body contact or said well contact; and
said semiconductor region of the first conductivity type surrounding said part of the region is replaced by said second diffusion region of the second conductivity type.

14. The method for producing a semiconductor integrated circuit device according to claim 10 wherein,
in said forming step, a third diffusion region of the first conductivity type is further formed in said semiconductor region of said first conductivity type;
said third diffusion region of the first conductivity type being arranged in isolation from said first diffusion region of said first conductivity type and being electrically connected to said first diffusion region of the first conductivity type; and wherein,
in said action-taking step, said first diffusion region of the first conductivity type and said third diffusion region of the first conductivity type are electrically isolated from each other.

15. The method for producing a semiconductor integrated circuit device according to claim 14 wherein, in said forming step, said first diffusion region of said first conductivity type and said third diffusion region of said first conductivity type are formed as a body contact or as a well contact; and wherein,
in said action-taking step, said first diffusion region of said first conductivity type is formed as a discharge path and said third diffusion region of said first conductivity type is formed as a body contact or as a well contact.
